(19) United States
(12) Patent Application Publication
(10) Pub. No.: US 2023/0369218 A1
(43) Pub. Date: Nov. 16, 2023

(54) INTERLEVEL VIA FOR STACKED FIELD-EFFECT TRANSISTOR DEVICE

(71) Applicant: INTERNATIONAL BUSINESS MACHINES CORPORATION, ARMONK, NY (US)

(72) Inventors: Tao Li, Slingerlands, NY (US); Devika Sarkar Grant, Amsterdam, NY (US); Liqiao Qin, Albany, NY (US); Nikhil Jain, Apple Valley, MN (US); Prabudhya Roy Chowdhury, Albany, NY (US); Sagarika Mukesh, Albany, NY (US); Ruilong Xie, Niskayuna, NY (US); Kisik Choi, Watervliet, NY (US)

(21) Appl. No.: 17/662,859

(22) Filed: May 11, 2022

(51) Int. Cl. H01L 23/528; H01L 21/8234; H01L 21/768; H01L 23/522; H01L 29/786

(52) U.S. Cl. CPC H01L 23/5286; H01L 21/823475; H01L 21/76897; H01L 23/5226; H01L 29/78696; H01L 29/0673

(57) ABSTRACT

Embodiments disclosed herein include a semiconductor structure. The semiconductor structure may include a first top transistor comprising a first source/drain (S/D) region and a first bottom transistor with a second S/D region. The first bottom transistor may be stacked directly below the first transistor. The semiconductor structure may also include a backside power delivery network (BSPDN) below the bottom transistor, a back-end-of-line (BEOL) metal level above the top transistor, and a first interlevel via electrically connecting a top of the first S/D region to the BSPDN.

### BACKGROUND

The present invention relates generally to the field of semiconductor device fabrication, and more particularly to fabricating an interlevel via for a field-effect transistor (FET) device stacked above or below another FET device.

In modern integrated circuits, such as microprocessors, storage devices and the like, a very large number of circuit elements, especially transistors, are provided on a restricted chip area. Transistors come in a variety of shapes and forms, e.g., planar transistors, FinFET transistors, nanowire devices, etc. The transistors are typically either NMOS (NFET) or PMOS (PFET) type devices wherein the “N” and “P” designation is based upon the type of dopants used to create the source/drain regions of the devices. So-called CMOS (Complementary Metal Oxide Semiconductor) technology or products refers to integrated circuit products that are manufactured using both NMOS and PMOS transistor devices. Irrespective of the physical configuration of the transistor device, each device comprises drain and source regions and a gate electrode structure positioned above and between the source/drain regions. Upon application of an appropriate control voltage to the gate electrode, a conductive channel region forms between the drain region and the source region.

As semiconductor microchips and integrated circuits become smaller, stacked FETs are an attractive option to provide higher transistor density in a given footprint by stacking one device over another.

### SUMMARY

Aspects of an embodiment of the present invention include a semiconductor structure. The semiconductor structure may include a first top transistor comprising a first source/drain (S/D) region and a first bottom transistor comprising a second S/D region. The first bottom transistor may be stacked directly below the first transistor. The semiconductor structure may also include a backside power delivery network (BSPDN) below the bottom transistor, a back-end-of-line (BEOL) metal level above the top transistor, and a first interlevel via electrically connecting a top of the first S/D region to the BSPDN.

Aspects of an embodiment of the present invention encompass a method of fabricating a semiconductor structure. The method may include forming a first bottom transistor, forming a first top transistor directly above the first bottom transistor, comprising a first top source/drain (S/D), forming a first interlevel via, and forming a middle-of-line (MOL) contact above the first top transistor. The MOL contact may connect the first top S/D with the first interlevel via. The method may also include forming a backside contact connected to a bottom of the first interlevel via and forming a backside power delivery network (BSPDN) connected to the backside contact.

### BRIEF DESCRIPTION OF THE DRAWINGS

FIG. 1 depicts a nanosheet transistor at a fabrication stage of the processing method, in accordance with one embodiment of the present invention;

FIGS. 2A, 2B, and 2C depict the semiconductor structure of FIG. 1 at a fabrication stage, in accordance with one embodiment of the present invention.

FIG. 2A is a cross-sectional side view along line A-A′ of FIG. 1;

FIG. 2B is a cross-sectional side view along line B-B′ of FIG. 1; and

FIG. 2C is a cross-sectional side view along line C-C′ of FIG. 1.

FIGS. 3A, 3B, and 3C depict the semiconductor structure of FIG. 1 at a subsequent fabrication stage, in accordance with one embodiment of the present invention.

FIG. 3A is a cross-sectional side view along line A-A′ of FIG. 1;

FIG. 3B is a cross-sectional side view along line B-B′ of FIG. 1; and

FIG. 3C is a cross-sectional side view along line C-C′ of FIG. 1.

FIGS. 4A, 4B, and 4C depict the semiconductor structure of FIG. 1 at a subsequent fabrication stage, in accordance with one embodiment of the present invention.

FIG. 4A is a cross-sectional side view along line A-A′ of FIG. 1;

FIG. 4B is a cross-sectional side view along line B-B′ of FIG. 1; and

FIG. 4C is a cross-sectional side view along line C-C′ of FIG. 1.

FIGS. 5A, 5B, and 5C depict the semiconductor structure of FIG. 1 at a subsequent fabrication stage, in accordance with one embodiment of the present invention.

FIG. 5A is a cross-sectional side view along line A-A′ of FIG. 1;

FIG. 5B is a cross-sectional side view along line B-B′ of FIG. 1; and

FIG. 5C is a cross-sectional side view along line C-C′ of FIG. 1.

FIGS. 6A, 6B, and 6C depict the semiconductor structure of FIG. 1 at a subsequent fabrication stage, in accordance with one embodiment of the present invention.

FIG. 6A is a cross-sectional side view along line A-A′ of FIG. 1;

FIG. 6B is a cross-sectional side view along line B-B′ of FIG. 1; and

FIG. 6C is a cross-sectional side view along line C-C′ of FIG. 1.

FIGS. 7A, 7B, and 7C depict the semiconductor structure of FIG. 1 at a subsequent fabrication stage, in accordance with one embodiment of the present invention.

FIG. 7A is a cross-sectional side view along line A-A′ of FIG. 1;

FIG. 7B is a cross-sectional side view along line B-B′ of FIG. 1; and

FIG. 7C is a cross-sectional side view along line C-C′ of FIG. 1.

FIGS. 8A, 8B, and 8C depict the semiconductor structure of FIG. 1 at a subsequent fabrication stage, in accordance with one embodiment of the present invention.

FIG. 8A is a cross-sectional side view along line A-A′ of FIG. 1;

FIG. 8B is a cross-sectional side view along line B-B′ of FIG. 1; and

FIG. 8C is a cross-sectional side view along line C-C′ of FIG. 1.

FIGS. 9A, 9B, and 9C depict the semiconductor structure of FIG. 1 at a subsequent fabrication stage, in accordance with one embodiment of the present invention.

FIG. 9A is a cross-sectional side view along line A-A′ of FIG. 1;

FIG. 9B is a cross-sectional side view along line B-B′ of FIG. 1; and

FIG. 9C is a cross-sectional side view along line C-C′ of FIG. 1.

### DETAILED DESCRIPTION

In the following detailed description, reference is made to the accompanying drawings, which show specific examples of embodiments of the invention. These embodiments are described in sufficient detail to enable those skilled in the art to practice them, and it is to be understood that other embodiments may be utilized and that structural, logical and electrical changes may be made without departing from the described embodiments. The following detailed description is, therefore, not to be taken in a limiting sense, and the included embodiments are defined by the appended claims.

With regard to the fabrication of transistors and integrated circuits, major surface refers to that surface of the semiconductor layer in and about which a plurality of transistors are fabricated, e.g., in a planar process. As used herein, the term “vertical” means substantially orthogonal with respect to the major surface. Typically, the major surface is along a plane of a monocrystalline silicon layer on which transistor devices are fabricated.

Improvements in the design of integrated circuits (IC) have enabled feature sizes for transistors in a device layer to enter into deep submicron and nanometer regime. Embodiments herein recognize benefits from separating the power delivery components from the signal wires. A backside power delivery network (BSPDN) and/or backside power rails (BPR), for example, can greatly improve the routability for field-effect transistor (FET). Improving routability means the design of the IC provides easier connection between source/drains, gates, etc. and the other components of the IC. The BSPDN and BPR enable space on a backside (i.e., below a plane at a bottom of the device layer) to be utilized for power delivery (e.g., metal levels of wires and vias to convey the power signals to the devices in the device layer) while space on a frontside (i.e., above a plane at a top of the device layer) can provide the signal wires with more room for misalignment without defects. For stacked FET, connections between top epi regions of the source/drains and the BSPDN/BPR can be difficult, however. Specifically, the formation of the contacts for source/drain regions for both top and bottom FETs to signal lines or power supplies is challenging because top device could shadow the bottom device during contact formation.

FIG. 1 depicts a schematic top view of a semiconductor structure 100, in accordance with one embodiment of the present invention. The semiconductor structure 100 includes rows 102 of stacked field-effect transistor (FET) devices and columns 104 of gate and source/drains (S/Ds) fabricated in a device layer 106a of the semiconductor device 100. The columns 104 include gates 108 and S/D contacts 110 that electrically connect upper devices (e.g., wire lines, metal levels) to the S/Ds and gate structures within the semiconductor structure 100 below. The semiconductor structure 100 also includes interlevel vias (IV) 112 to electrically connect certain S/Ds to a back-end-of-line (BEOL) interconnect network on a front side 106b (illustrated in subsequent figures below) above the device layer 106a of the semiconductor structure 100 and other S/Ds to a backside power delivery network (BSPDN) on a back side 106c (illustrated in subsequent figures below) below the device layer 106a. The semiconductor structure 100 includes other components (e.g., shallow trench isolation, interlayer dielectric) that are not illustrated in FIG. 1 so that the rows and columns of the semiconductor structure 100 may be more easily described.

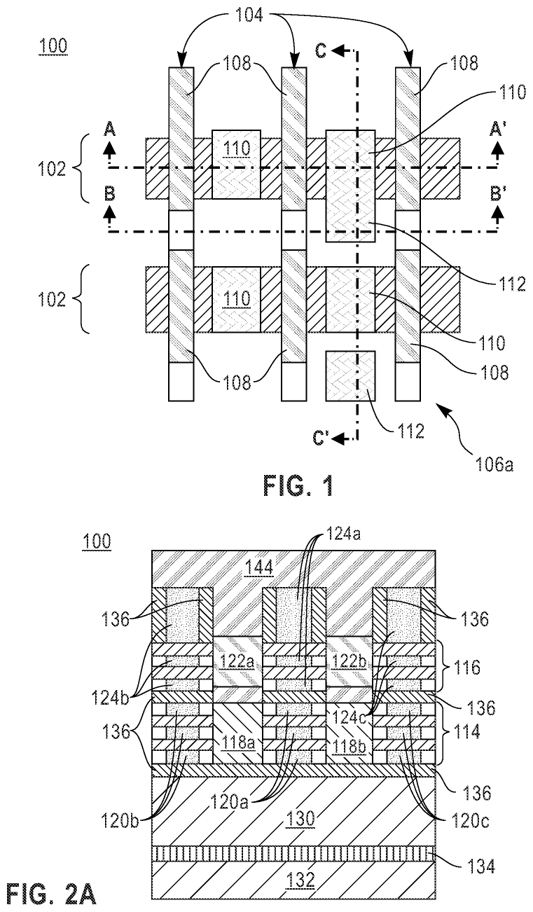

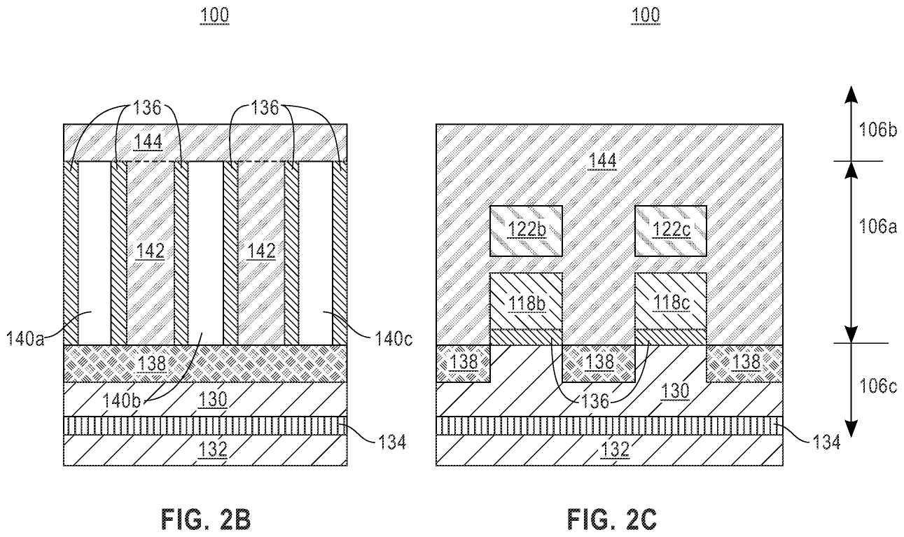

FIGS. 2A, 2B, and 2C depict the semiconductor structure 100 of FIG. 1 at a fabrication stage, in accordance with one embodiment of the present invention. FIG. 2A is a cross-sectional side view of one row 102 of the semiconductor structure 100 along line A-A′ of FIG. 1; FIG. 2B is a cross-sectional side view between rows 102 of the semiconductor structure 100 along line B-B′ of FIG. 1; and FIG. 2C is a cross-sectional side view between columns 104 of the semiconductor structure 100 along line C-C′ of FIG. 1. The semiconductor structure 100 includes bottom nanosheet FETs 114 stacked directly below top nanosheet FETs 116 in the device layer 106a. The bottom nanosheet FETs 114 include a first bottom source/drain (S/D) 118a (FIG. 1A), a second bottom S/D 118b (FIGS. 1A and 1C), and a third bottom S/D 118c (FIG. 1C). The first bottom S/D 118a and the second bottom S/D 118b are separated by a first bottom gate 120a. Additional bottom gates 120b, c may be formed around the bottom S/Ds 118a, b, c along each of the rows 102.

Similarly to the bottom FETs 114, the top nanosheet FETs 116 include a first top source/drain (S/D) 122a (FIG. 1A), a second top S/D 122b (FIGS. 1A and 1C), and a third bottom S/D 122c (FIG. 1C). The first top S/D 122a and the second top S/D 122b are separated by a first top gate 124a. Additional top gates 124b, c may be formed around the top S/Ds 122a, b, c along each of the rows 102.

The nanosheet FETs 114, 116 may be formed, for example, as alternating series of layers and sacrificial layers in vertical layer stacks. The layers (i.e., nanosheets or nanowires) may be composed of a semiconductor material, such as silicon (Si). The sacrificial layers may include a different semiconductor material, such as silicon germanium (SiGe). The layers of the FETs 114, 116 may be formed by an epitaxial growth process. After the layers are built up, the sacrificial layers are removed cleanly from the semiconductor material of the FETs 114, 116. As used herein, the term “cleanly” in reference to a material removal process (e.g., etching) denotes that, with an appropriate etchant choice, the material removal rate (i.e., etch rate) for the targeted material is greater than the removal rate for at least another material exposed to the material removal process. The number of layers in the FETs 114, 116 may differ (more layers or fewer layers) from the number depicted in the representative embodiment.

A device substrate 130 supports the steps of fabricating the device layer 106a and the front side 106b of the semiconductor structure 100 and is structurally strengthened by a structural substrate 132 that is separated from the device substrate 130 by an etch-stop layer 134. Certain embodiments may also include a middle dielectric isolation (MDI) 136 that isolates the bottom FETs 114 from the device substrate 130. The bottom FETs 114 may also be separated from the top FETs 116 by MDI 136 along the columns 104 of gates 108.

The rows 102 of FET devices are isolated by shallow trench isolation (STI) 138, which may be a buried oxide (BOX) layer of a semiconductor-on-insulator (SOI) substrate or dielectric isolation in a bulk substrate. Above the STI 138 in the device layer 106a, the semiconductor structure 100 includes gate cuts 140a, b, c, as shown in FIG. 2B. Each gate cut 140a, b, c is insulated from other gate cuts 140a, b, c by interlayer dielectric (ILD) 142 that may be formed after forming bottom and top source/drain regions. The ILD 142 may also be formed between the bottom FETs 114 and the top FETs 116. The semiconductor structure 100 may include middle-of-line (MOL) ILD 144 that is deposited above the FETs 114, 116 and the gate cuts 140 after replacement gate formation.

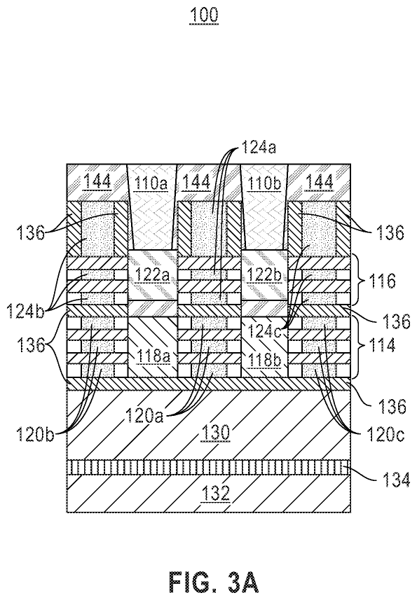

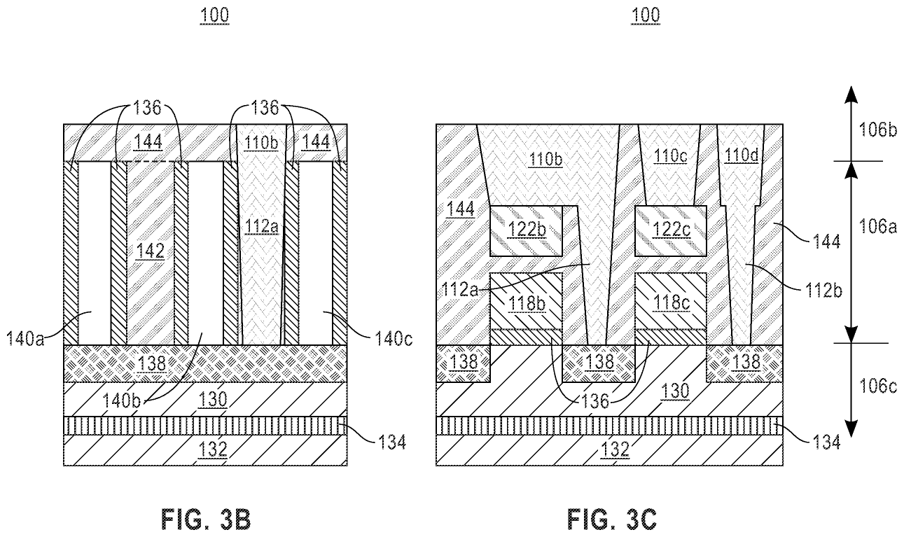

FIGS. 3A, 3B, and 3C depict cross-sectional side views of the semiconductor structure 100 of FIG. 1 at a subsequent fabrication stage, in accordance with one embodiment of the present invention. The cross-sectional side views are from the same locations as the figures above. The semiconductor structure 100 includes contacts 110a, b, c, d that are first formed as holes etched through the MOL ILD 144 and the ILD 142 to the top S/Ds 122a, b, c. The contacts 110a, b, c, d may be etched using lithographical patterning and etch processes such as extreme ultra-violet (EUV) lithography and plasma dry etch process. After the holes for the contacts 110a, b, c, d are etched, holes for the IVs 112a, b may also be etched down to the STI 138. The interlevel-vias 112a and 112b are placed next to gate cut region 140, such that even if the deep via etch process were to damage the gate spacer, such damage would not cause shorts between the deep via and the gate. The holes are then filled with a conductive material, such as metal, and may also include a silicide liner, an adhesion metal liner, and/or a conductive metal fill. The semiconductor structure 100 may then be polished to be flush with the MOL ILD 144.

Since the holes for the contacts 110a, b, c, d and the IVs 112a, b are formed from the front side 106b, the contacts 110a, b, c, d and the IVs 112a, b will etch faster at the top than the bottom. The etch process thus results in a taper from top to bottom. A taper, as defined herein, is a direction from a wider part to a narrower part. That is, the contacts 110a, b, c, d and the IVs 112a, b are wider at the top (i.e., the top of the MOL ILD) than at the bottom (i.e., at the connection to the S/Ds 122a, b, c or the IV 112a, b).

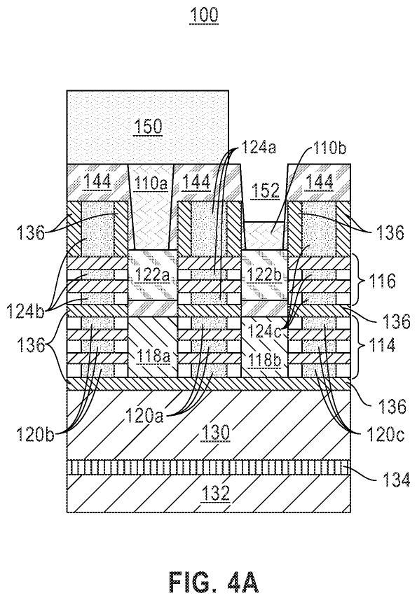

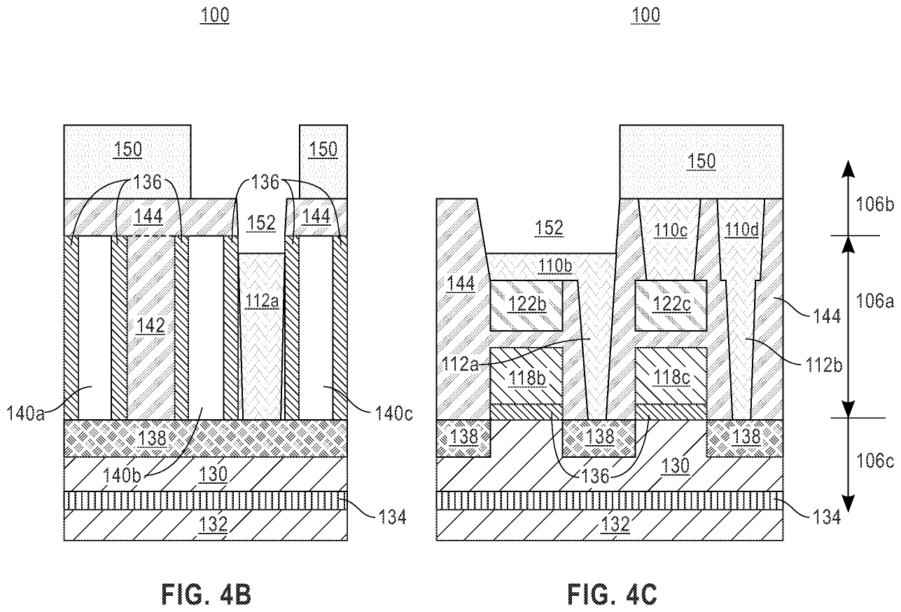

FIGS. 4A, 4B, and 4C depict cross-sectional side views of the semiconductor structure 100 of FIG. 1 at a fabrication stage of the processing method, in accordance with one embodiment of the present invention. The cross-sectional views are from the same locations as the figures above. The semiconductor structure 100 includes a patterning mask 150 that is formed on the top surface of the MOL ILD 144. The patterning mask 150 may be composed of a conventional organic thin films used in lithography process, such as OPL, or a hardmask material, such as silicon nitride, or other materials that are deposited (e.g., by chemical vapor deposition (CVD)) and patterned using a litho patterning process. The patterning enables an etching process whereby a recess 152 may be formed above the second contact 110a. The recess 152 decreases the height of the second contact 110b, but does not significantly increase the electrical resistance of the second contact 110a between the second top S/D 122b and the first IV 112a. Because the top source/drain region 122b is connected to an interlevel via 112a to the backside of the wafer, the top portion of the metal in 110b and 112a are no longer needed to wire the 122b to frontside BEOL interconnect, the metal is recessed to reduce the parasitic capacitance between metal and gates, or between metal lines. This also reduce the MOL and lower BEOL congestions above that area.

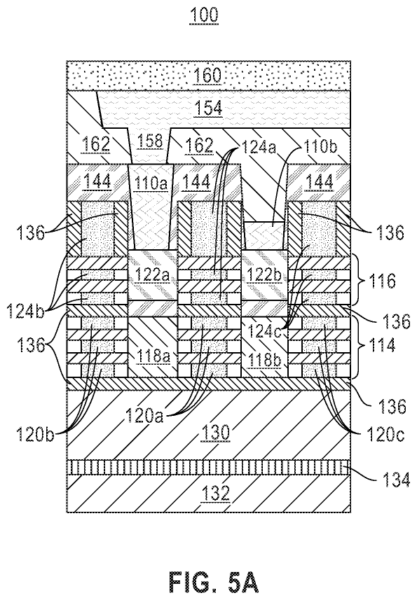

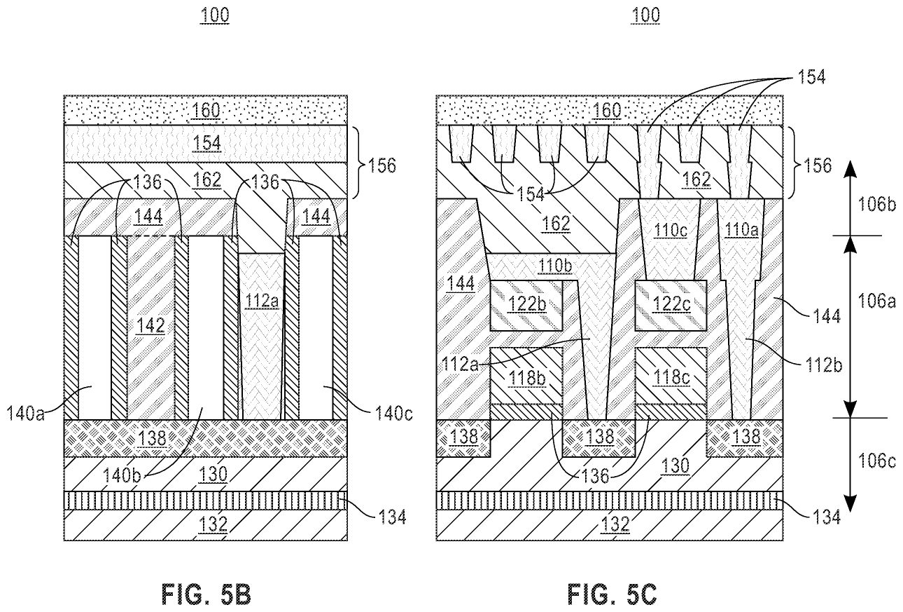

FIGS. 5A, 5B, and 5C depict cross-sectional side views of the semiconductor structure 100 of FIG. 1 at a subsequent fabrication stage of the processing method, in accordance with one embodiment of the present invention. The cross-sectional side views are from the same locations as the figures above. The semiconductor structure 100 includes signal wires 154 of a first metal level 156, and vias 158 connecting the signal wires 154 to the first contact 110a, the third contact 110c, and the fourth contact 110d. Although not to scale, FIGS. 5A, 5B, and 5C show additional back-end-of-line (BEOL) metal levels 160 that electrically connect to the first metal level 156 to pins which contact the semiconductor structure 100 with other devices. The conductive components (i.e., signal wires 154 and vias 158) of the first metal level 156 are patterned and etched into a first metal level dielectric 162.

The recess 152, shown in FIGS. 4A, B, and C, is also filled with the first metal level dielectric 162. The first metal level dielectric 162 insulates the second contact 110b from the first metal level 156, and therefore isolates the second top S/D 122b from the BEOL metal levels 160 directly. As illustrated below, the second top S/D 122b is instead electrically connected to power through the backside 106c of the semiconductor structure 100. That is, the recess 152 does not include any conductive components of the first metal level 156. The second contact 110b, therefore, is unlikely to conduct a signal from the second top S/D 122b to the first metal level 156.

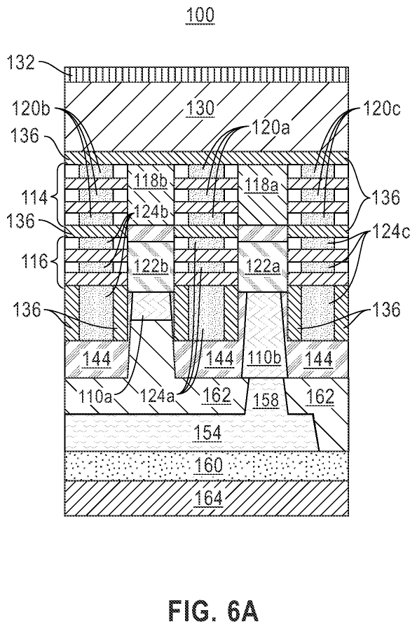

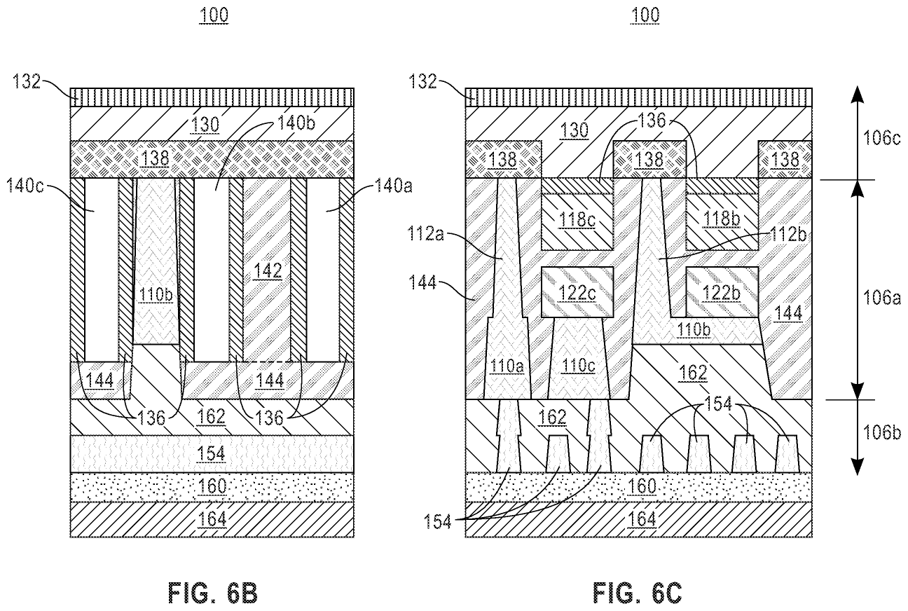

FIGS. 6A, 6B, and 6C depict cross-sectional side views of the semiconductor structure 100 of FIG. 1 at a subsequent fabrication stage of the processing method, in accordance with one embodiment of the present invention. The cross-sectional side views are from the same locations as the figures above. The semiconductor structure 100 includes a carrier wafer 164 that enables fabrication of the semiconductor structure 100 to continue on the backside 106c after flipping the semiconductor structure 100 so the carrier wafer 164 supports the semiconductor structure 100 from underneath. Certain embodiments may include a step or steps to be completed with the carrier wafer 164 oriented at the top of the semiconductor structure 100, but since the formation of the BSPDN typically happens from above, FIGS. 6A, 6B, 6C and the following figures will be oriented with the carrier wafer 164 on the bottom. The semiconductor structure 100 has the structural substrate 134 removed down to the etch-stop layer 132. The presence of the etch-stop layer 132 enables structural substrate 134 to be removed without damaging the device substrate 130, STI 138, S/D 118, 122 or gates 108. The substrate 134 removal can begin with a rough etch process that removes the structural substrate 134 faster than other fine etch processes. The rough etch process has a potential for uneven etching, and it does not have etch selectivity. After the rough etch process, a fine and highly selective etch is used to remove any remaining structural substrate 134, stopping on the etch-stop layer 132 so the device substrate 130 and other components of the semiconductor structure 100 do not get etched or damaged.

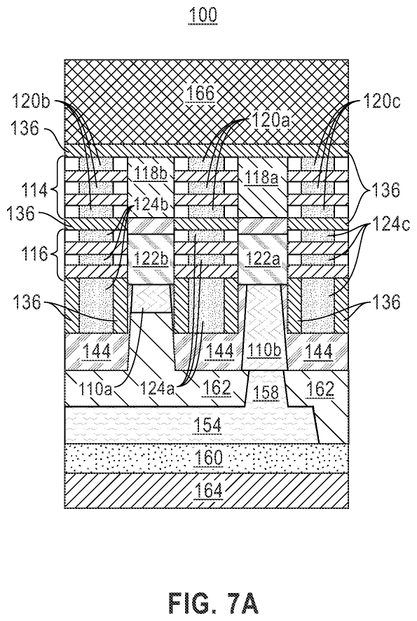

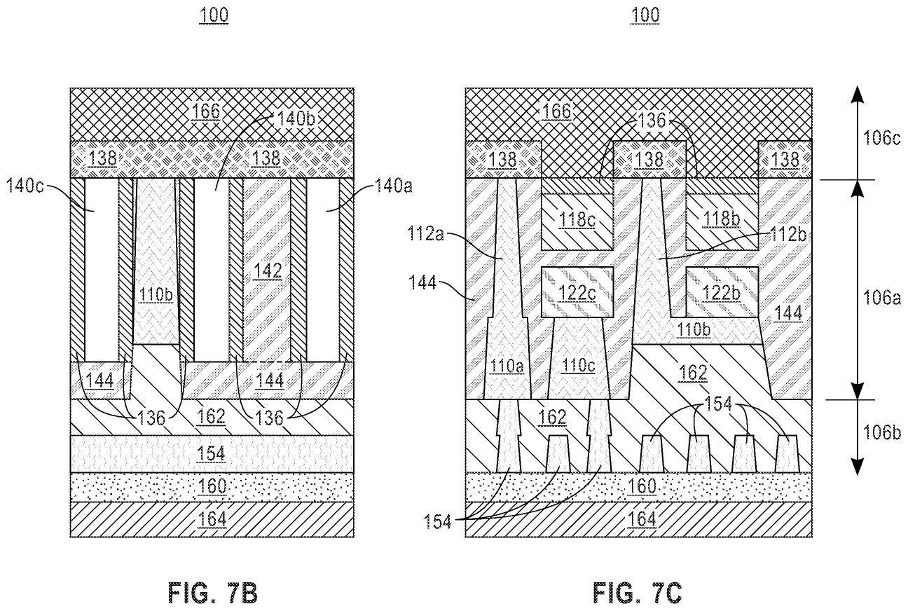

FIGS. 7A, 7B, and 7C depict cross-sectional side views of cross-sectional side views of the semiconductor structure 100 of FIG. 1 at a subsequent fabrication stage of the processing method, in accordance with one embodiment of the present invention. The cross-sectional views are from the same locations as the figures above. The semiconductor structure 100 shows the etch-stop layer 132 and the device substrate 130 removed from the MDI 136 and the STI 138. The etch-stop layer 132 and the device substrate 130 have been replaced by an insulative backside ILD 166. The backside ILD 166 may be formed from the same material as the ILD 142 or the MOL ILD 144. In certain embodiments, the backside ILD 166 is formed from a different material than the ILD 142 and the MOL ILD 144.

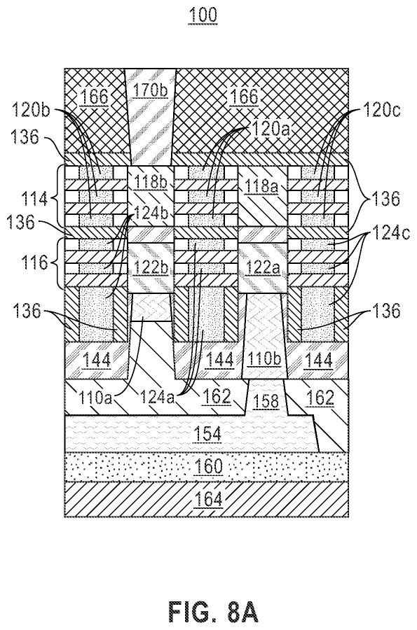

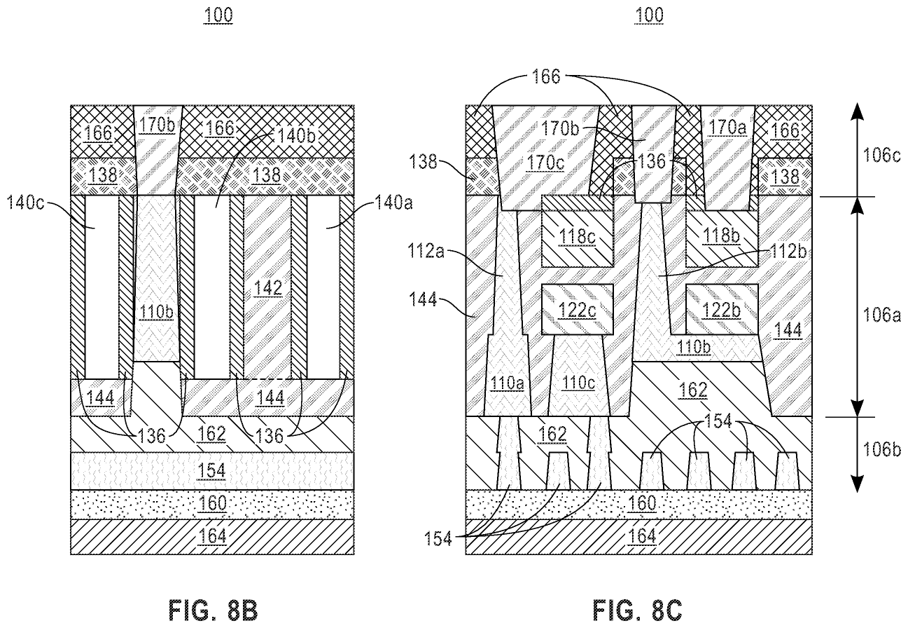

FIGS. 8A, 8B, and 8C depict cross-sectional side views of cross-sectional side views of the semiconductor structure 100 of FIG. 1 at a subsequent fabrication stage of the processing method, in accordance with one embodiment of the present invention. The cross-sectional views are from the same locations as the figures above. The semiconductor structure 100 includes backside contacts 170a, b, c that are formed through the backside ILD 166 using the patterning and etching processes described above. The backside contacts 170a, b, c are formed from the backside 106c of the semiconductor structure 100, and thus have a taper that is opposite the taper for the contacts 110a, b, c, d and the IVs 112a, b.

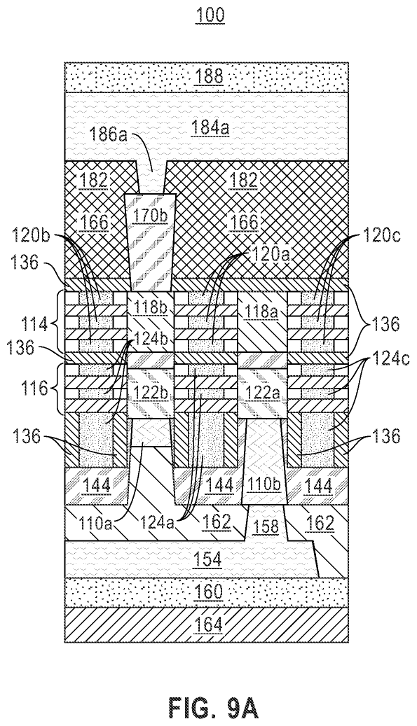

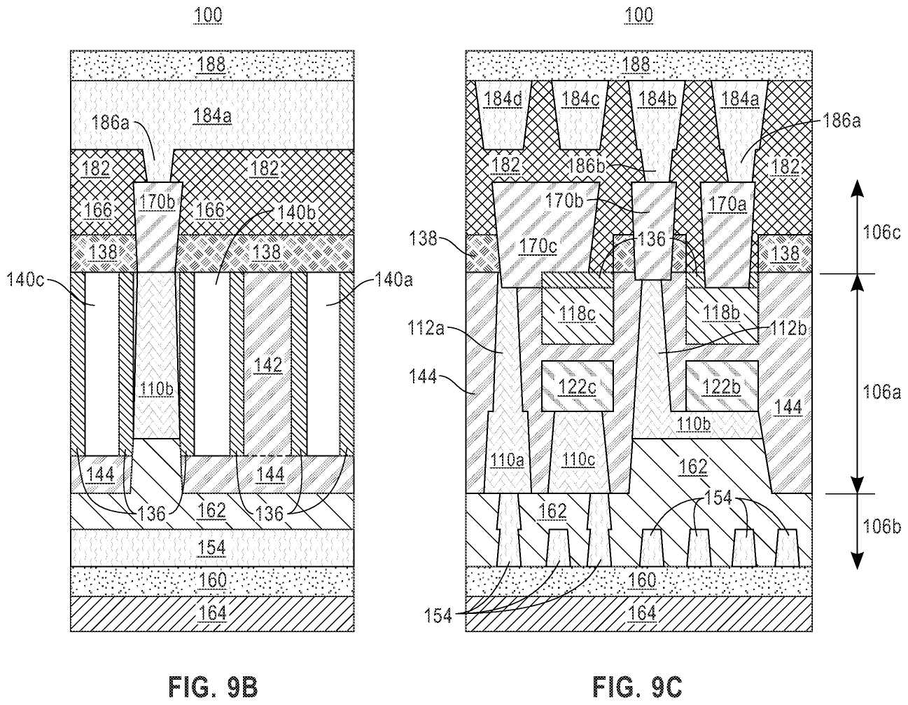

FIGS. 9A, 9B, and 9C depict cross-sectional side views of cross-sectional side views of the semiconductor structure 100 of FIG. 1 at a subsequent fabrication stage of the processing method, in accordance with one embodiment of the present invention. The cross-sectional views are from the same locations as the figures above. The semiconductor structure 100 includes a BSPDN 180 that is formed on the backside ILD 166 after additional backside ILD 182 is formed. The BSPDN 180 may include power wires 184a, b, c, d, and vias 186a, b that electrically connect the first backside contact 170a and the second backside contact 170b to additional power levels 188. The third backside contact 170c does not electrically connect to the BSPDN 180, but rather connects to the second via 112b so that the third bottom S/D 118c is able to electrically connect to the BEOL metal levels (i.e., to BEOL signal wires) 160 through the second via 112b and the fourth contact 110d.

Therefore, embodiments disclosed herein include top S/Ds that electrically connect to a BSPDN without affecting the bottom S/D directly below; and bottom S/Ds that electrically connect to BEOL metal levels without affecting the top S/D directly above. Specifically, in the illustrated embodiment the second top S/D 122b is electrically connected to the BSPDN 180 without detriment to the bottom S/D 118b that is directly below the second top S/D 122b. The electrical connection is facilitated by the first IV 112a that pass between top S/Ds (i.e., second top S/D 122b and third top S/D 122c), between bottom S/Ds (i.e., second bottom S/D 118b and third bottom S/D 118c), and between the second gate cut 140b and the third gate cut 140c. Also, the third bottom S/D 118c is electrically connected to the BEOL metal levels 160 without detriment to the top S/D 122c. The electrical connection is facilitated by the second IV 112b adjacent to the third top S/D 122c and the third bottom S/D 118c.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first top transistor comprising a first source/drain (S/D) region;
a first bottom transistor comprising a second S/D region, wherein the first bottom transistor is stacked directly below the first transistor;
a backside power delivery network (BSPDN) below the bottom transistor;
a back-end-of-line (BEOL) metal level above the top transistor; and
a first interlevel via electrically connecting a top of the first S/D region to the BSPDN.

2. The semiconductor structure of claim 1, further comprising:
a second top transistor adjacent to the first top transistor;
a second bottom transistor adjacent to the first bottom transistor and directly below the second top transistor, wherein the first interlevel via is located between the first top transistor and the second top transistor, and wherein the first interlevel is located between the first bottom transistor and the second bottom transistor.

3. The semiconductor structure of claim 2, further comprising:
a second interlevel via electrically connecting the second bottom transistor to the BEOL interconnect network.

4. The semiconductor structure of claim 3, further comprising a backside contact located between the second interlevel via and the BSPDN, wherein the backside contact is tapers from bottom to top, and the second interlevel via tapers from top to bottom.

5. The semiconductor of claim 2, further comprising:
a first top middle-of-line (MOL) contact connecting the first S/D region to the first interlevel via;
a second top MOL contact connect the second top transistor to the BEOL interconnect network, wherein the first top MOL contact is recessed below the second top MOL contact.

6. The semiconductor structure of claim 1, wherein the first interlevel via tapers from top to bottom.

7. The semiconductor structure of claim 6, further comprising a backside contact between the first interlevel via and the BSPDN, wherein the backside contact tapers from bottom to top.

8. A method of fabricating a semiconductor structure, comprising:
forming a first bottom transistor;
forming a first top transistor directly above the first bottom transistor, comprising a first top source/drain (S/D);
forming a first interlevel via;
forming a middle-of-line (MOL) contact above the first top transistor, wherein the MOL contact connects the first top S/D with the first interlevel via;
forming a backside contact connected to a bottom of the first interlevel via;
forming a backside power delivery network (BSPDN) connected to the backside contact.

9. The method of claim 8, comprising:
forming a second top transistor adjacent to the first top transistor;
forming a second bottom transistor adjacent to the first bottom transistor and directly below the second top transistor, wherein the first interlevel via is located between the first top transistor and the second top transistor, and between the first bottom transistor and the second bottom transistor.

10. The method of claim 9, further comprising forming a second interlevel via electrically connecting the second bottom transistor to a back-end-of-line (BEOL) interconnect network.

11. The method of claim 10, further comprising forming a second backside contact between the second interlevel via and the BSPDN, wherein the second interlevel via is formed from a top side of the semiconductor structure, and the backside contact is formed from a bottom side of the semiconductor structure.

12. The method of claim 8, further comprising forming the backside contact from a bottom side of the semiconductor structure opposite the top side.

13. The method of claim 8, further comprising recessing the MOL contact.

14. The method of claim 8, further comprising forming a back-end-of-line (BEOL) interconnect network before forming the BSPDN.

15. A semiconductor structure, comprising:
a first top transistor comprising a first source/drain (S/D) region;
a first bottom transistor comprising a second S/D region stacked directly below the first transistor;
a backside power delivery network (BSPDN) below the bottom transistor;
a back-end-of-line (BEOL) interconnect network above the top transistor; and
a first interlevel via electrically connecting a bottom of the second S/D region to the BEOL interconnect network.

16. The semiconductor structure of claim 15, further comprising:
a second interlevel via electrically connecting the second bottom transistor to the BEOL interconnect network.

17. The semiconductor structure of claim 16, further comprising a backside contact located between the second interlevel via and the BSPDN, wherein the backside contact is insulated from the BSPDN tapers from bottom to top, and the second interlevel via tapers from top to bottom.

18. The semiconductor structure of claim 15, further comprising:
a first top middle-of-line (MOL) contact connecting the first S/D region to the first interlevel via;
a second top MOL contact connect the second top transistor to the BEOL interconnect network, wherein the first top MOL contact is recessed below the second top MOL contact.

19. The semiconductor structure of claim 15, wherein the first interlevel via tapers from top to bottom.

20. The semiconductor structure of claim 19, further comprising a backside contact between the first interlevel via and the BSPDN, wherein the backside contact tapers from bottom to top.
